(19) United States
(12) Patent Application Publication
(10) Pub. No.: US 2010/0319968 A1
(43) Pub. Date: Dec. 23, 2010

(54) ALUMINUM CIRCUIT BOARD AND METHOD AND ELECTROPLATING SOLUTION FOR MAKING THE SAME

(76) Inventors: Fu-Hsiang Yao, Changhua City (TW); Shih-Yao Huang, Liouguei Township (TW)

Correspondence Address: MERCHANT & GOULD PC, P.O. BOX 2903, MINNEAPOLIS, MN, 55402-0903, US

(21) Appl. No.: 12/701,167

(22) Filed: Feb. 5, 2010

(30) Foreign Application Priority Data
Jun. 19, 2009 (TW) 098120555

(51) Int. Cl. H05K 1/09; H05K 1/05; C25D 11/12

(52) U.S. Cl. 174/257; 174/258; 205/175

(57) ABSTRACT

An aluminum circuit board includes a body unit and a conductive wiring unit. The body unit includes an aluminum substrate, an alumina layer formed on the aluminum substrate, and a medium deposit formed on the alumina layer and made of nickel, copper, cobalt, iron, silver, zinc, tin, molybdenum, or combinations thereof. The conductive wiring unit is formed on the body unit and is bonded to the medium deposit.

### CROSS-REFERENCE TO RELATED APPLICATION

This application claims priority of Taiwanese Application No. 098120555, filed on Jun. 19, 2009.

### BACKGROUND OF THE INVENTION

1. Field of the Invention

The invention relates to an aluminum circuit board, more particularly to an aluminum circuit board having improved bonding property, heat dissipation, and high voltage resistance. The invention also relates to a method and an electroplating solution for making the aluminum circuit board.

2. Description of the Related Art

Referring to FIG. 1, a conventional aluminum circuit board 1 includes an aluminum substrate 11, an insulating layer 12 formed on the aluminum substrate 11, and a metal conductive wiring layer 13 formed on the insulating layer 12. Diamond-like carbon is a material commonly used for the insulating layer 12. However, diamond-like carbon has inferior insulation, the breakdown voltage thereof is unsatisfactory, and situations such as electric leakage or short circuit may occur in use. Furthermore, the insulating layer 12 and the metal conductive wiring layer 13 are liable to strip or separate from each other due to the material difference therebetween.

Another conventional method for making an aluminum circuit board is conducted by anodizing an aluminum substrate so as to form an alumina layer on the aluminum substrate as the insulating layer. Colloidal silver or colloidal copper is sintered on the insulating layer at an elevated temperature to form the metal conductive wiring layer. However, the insulating layer is liable to crack at the elevated temperature, which may lead to electric leakage.

In order to overcome the aforesaid shortcoming, yet another method for making an aluminum circuit board uses a rein material to glue a copper foil to an aluminum substrate with or without anodization. However, the resin material has inferior heat conductivity, which leads to unsatisfactory heat conductivity of the aluminum circuit board. Although the heat conductivity of the aluminum circuit board may be improved by adding ceramic powders into the resin material, the improvement is still unsatisfactory.

### SUMMARY OF THE INVENTION

Therefore, an object of the present invention is to provide an aluminum circuit board having improved bonding property, heat dissipation, and high voltage resistance.

Another object of the present invention is to provide a method for making the aluminum circuit board.

Yet another object of the present invention is to provide an electroplating solution for making the aluminum circuit board.

In one aspect of this invention, an aluminum circuit board includes a body unit and a conductive wiring unit. The body unit includes an aluminum substrate, an alumina layer formed on the aluminum substrate, and a medium deposit formed on the alumina layer and made of nickel, copper, cobalt, iron, silver, zinc, tin, molybdenum, or combinations thereof. The conductive wiring unit is formed on the body unit and is bonded to the medium deposit.

In another aspect of this invention, a method for making an aluminum circuit board includes the steps of: a) preparing an electroplating solution containing 10-50 wt % of an acid, 0.01-0.05 wt % of a surfactant, 0.5-1 wt % of a metal salt, and a balance of a solvent, based on the total weight of the electroplating solution, the acid being sulfuric acid, oxalic acid, tartaric acid, sulfosalicylic acid, maleic acid, lactic acid, phosphoric acid, or combinations thereof, the surfactant being sorbitol, sodium sulfonate, nitric acid, citric acid, potassium sodium tartrate, or combinations thereof, the metal salt being a salt of nickel, copper, cobalt, iron, silver, tin, molybdenum, or combinations thereof; b) soaking at least a surface of an aluminum substrate in the aqueous electroplating solution to anodize the aluminum substrate and to form an alumina layer on the aluminum substrate and a medium deposit on the alumina layer; and c) forming a conductive wiring unit on the medium deposit.

In yet another aspect of this invention, an electroplating solution for making an aluminum circuit board includes 10-50 wt %, based on the electroplating solution, of sulfuric acid, oxalic acid, tartaric acid, sulfosalicylic acid, maleic acid, lactic acid, phosphoric acid, or combinations thereof; 0.01-0.05 wt %, based on the electroplating solution, of sorbitol, sodium sulfonate, nitric acid, citric acid, potassium sodium tartrate, or combinations thereof as a surfactant; 0.5-1 wt %, based on the electroplating solution, of a salt of nickel, copper, cobalt, iron, silver, tin, molybdenum, or combinations thereof; and a balance of water, ethanol, ethylene glycol, or combinations thereof as a solvent.

### BRIEF DESCRIPTION OF THE DRAWINGS

Other features and advantages of the present invention will become apparent in the following detailed description of the preferred embodiments with reference to the accompanying drawings, of which:

FIG. 1 is a schematic view of a conventional aluminum circuit board;

FIG. 2 is a schematic view of a first preferred embodiment of an aluminum circuit board according to this invention;

FIG. 3 is a microscopic view of the first preferred embodiment;

FIG. 4 is a schematic view of a second preferred embodiment of an aluminum circuit board according to this invention;

FIG. 5 is a microscopic view of the second preferred embodiment;

FIG. 6 is a fragmentary sectional view of a third preferred embodiment of an aluminum circuit board according to this invention;

FIG. 7 is a fragmentary perspective view of a body unit for making the third preferred embodiment;

FIG. 8 is a fragmentary sectional view of a fourth preferred embodiment of an aluminum circuit board according to this invention; and

FIG. 9 is a fragmentary perspective view of a body unit for making the fourth preferred embodiment.

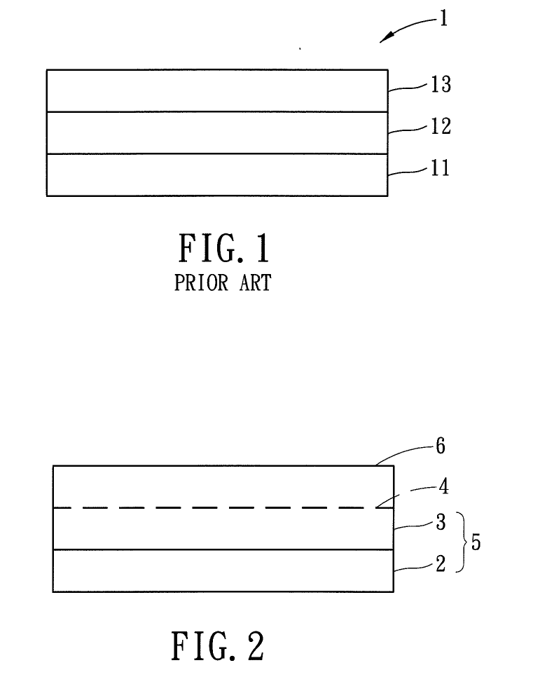

### DETAILED DESCRIPTION OF THE PREFERRED EMBODIMENTS

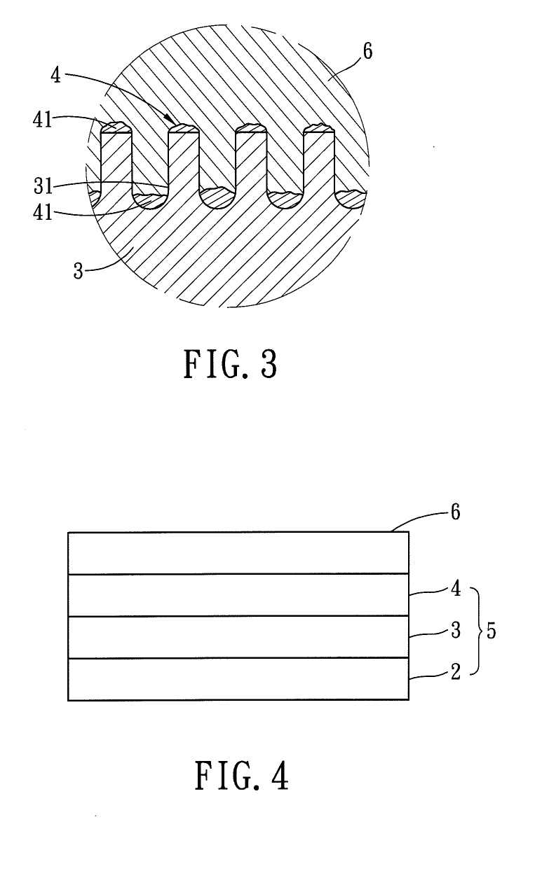

Referring to FIGS. 2 and 3, the first preferred embodiment of an aluminum circuit board according to this invention is shown to include a body unit 5 and a conductive wiring unit 6. The body unit 5 includes an aluminum substrate 2, an alumina layer 3 formed on the aluminum substrate 2, and a medium deposit 4 formed on the alumina layer 3.

The alumina layer 3 preferably has a thickness ranging from 10 μm to 300 μm. The medium deposit 4 can be made of nickel, copper, cobalt, iron, silver, zinc, tin, molybdenum, or combinations thereof. In the preferred embodiment, the medium deposit 4 is disposed dispersedly on the alumina layer 3. Specifically, as shown in FIG. 3, the alumina layer 3 includes a plurality of holes 31 spaced apart from each other. The medium deposit 4 includes a plurality of medium spots 41 disposed dispersedly in the holes 31 and/or on the alumina layer 3 between adjacent ones of the holes 31.

The conductive wiring unit 6 is formed on the body unit 5 and is bonded to the medium deposit 4. The conductive wiring unit 6 can be made of aluminum, gold, nickel, copper, cobalt, iron, silver, zinc, tin, molybdenum, or combinations thereof, and has a predetermined circuit pattern.

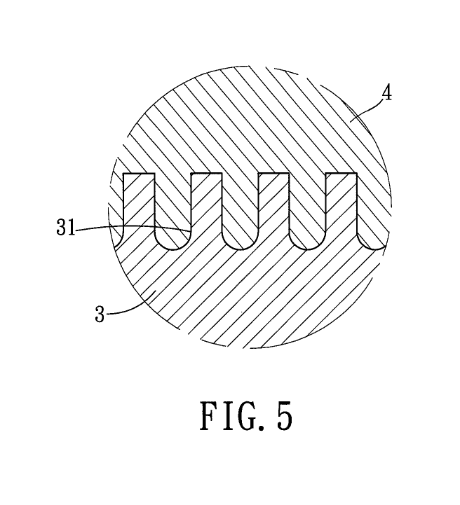

Referring to FIGS. 4 and 5, the second preferred embodiment of an aluminum circuit board according to this invention is shown to be similar to the first preferred embodiment except that the medium deposit 4 is an intact layer formed on the alumina layer 3.

The method for making the aluminum circuit board includes the steps of:

A) preparing an electroplating solution:

The electroplating solution contains 10-50 wt % of an acid, 0.01-0.05 wt % of a surfactant, 0.5-1 wt % of a metal salt, and a balance of a solvent, based on the total weight of the electroplating solution.

The acid is used for promoting the formation of the alumina layer 3, and examples of the acid suitable for the present invention include sulfuric acid, oxalic acid, tartaric acid, sulfosalicylic acid, maleic acid, lactic acid, phosphoric acid, an combinations thereof. The amount of the acid preferably ranges from 15 wt % to 40 wt %, and more preferably ranges from 22 wt % to 30 wt %, based on the total weight of the electroplating solution.

The surfactant is used for improving the evenness of the alumina layer 3, and examples of the surfactant suitable for the present invention include sorbitol, sodium sulfonate, nitric acid, citric acid, potassium sodium tartrate, and combinations thereof. The amount of the surfactant preferably ranges from 0.02 wt % to 0.04 wt %, and more preferably is 0.01 wt %, based on the total weight of the electroplating solution.

The metal salt is used for forming the medium deposit 4, and examples of the metal salt suitable for the present invention include a salt of nickel, copper, cobalt, iron, silver, tin, molybdenum, and combinations thereof. Preferably, the metal salt is a copper salt, an iron salt, a molybdenum salt, or combinations thereof. More preferably, the metal salt is a copper salt, such as copper sulfate or copper acetate, or an iron salt, such as ferric sulfate. The amount of the metal salt preferably ranges from 0.65 wt % to 0.9 wt %, and more preferably from 0.55 wt % to 0.75 wt %, based on the total weight of the electroplating solution.

Examples of the solvent suitable for the present invention include water, ethanol, ethylene glycol, and combinations thereof.

It should be noted that the electroplating solution can be prepared by diluting a pre-formulated concentrate for the electroplating solution with a suitable amount of the solvent.

B) soaking:

A surface of an aluminum substrate 2 is soaked in the aqueous electroplating solution to anodize the aluminum substrate 2 and to form the alumina layer 3 on the aluminum substrate 2 and the medium deposit 4 on the alumina layer 3. The thickness of the alumina layer 3 formed thereby is not limited, but preferably ranges from 10 μm to 300 μm, and more preferably is 60 μm.

Preferably, the anodization is conducted using an operating voltage ranging from 10 to 250 V at a temperature ranging from 0 to 40° C. More preferably, the anodization is conducted using an operating voltage ranging from 50 to 60 V at a temperature ranging from 10 to 20° C.

C) forming a conductive wiring unit:

The conductive wiring unit 6 is formed on the medium deposit 4 by any suitable treatment well known in the art, such as vapor depositing or electroplating.

When the concentration of the metal salt in the electroplating solution is relatively low or the anodization is conducted for a relatively short period, the medium deposit 4 is formed on the alumina layer 3 in a manner of the medium spots 41 disposed dispersedly on the alumina layer 3, as best shown in FIG. 3. Therefore, the first preferred embodiment shown in FIG. 2 is obtained after the conductive wiring unit 6 is formed on the medium deposit 4.

On the other hand, when the concentration of the metal salt in the electroplating solution is sufficiently high or the anodization is conducted for a sufficiently long period, the medium deposit 4 is formed on the alumina layer 3 in a manner of a layer, as best shown in FIG. 5. Therefore, the second preferred embodiment shown in FIG. 4 is obtained after the conductive wiring unit 6 is formed on the medium deposit 4.

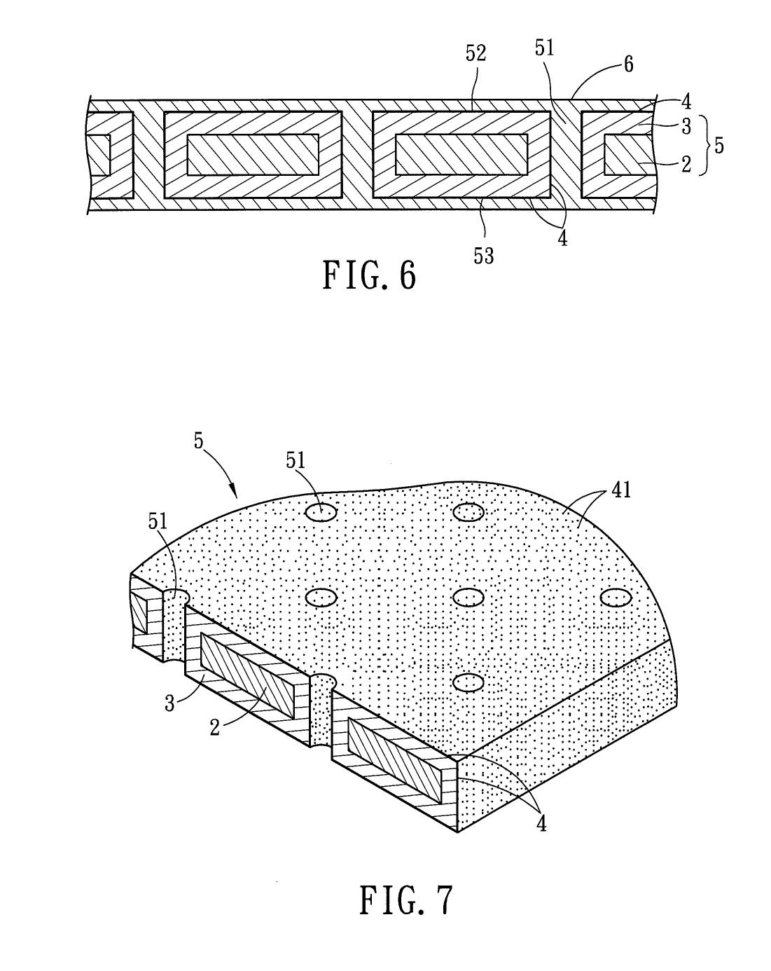

Referring to FIG. 6, the third preferred embodiment of an aluminum circuit board according to this invention is shown, in which the body unit 5 has a top surface 52, a bottom surface 53, and a plurality of through holes 51 extending through the top surface 52 and the bottom surface 53, and in which the conductive wiring unit 6 extends through the through holes 51 and is formed on the top and bottom surfaces 52, 53 of the body unit 5. Furthermore, in this preferred embodiment, the medium deposit 4 is formed in a manner of a plurality of medium spots disposed dispersedly on the alumina layer 3.

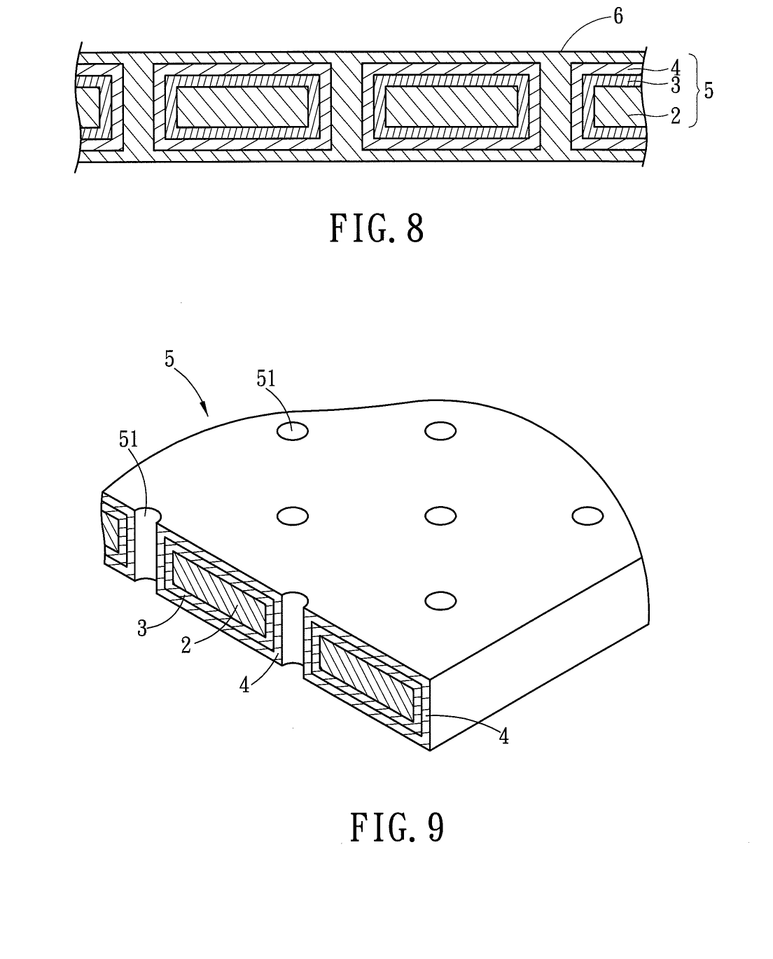

Referring to FIG. 8, the fourth preferred embodiment of an aluminum circuit board according to this invention is shown to be similar to the third preferred embodiment, expect that the medium deposit 4 is an intact layer formed on the alumina layer 3.

The method for making the third and fourth preferred embodiments is similar to the method for making the first and second preferred embodiment, except that the aluminum substrate 2 used for making the third and fourth preferred embodiments has a plurality of through holes and is fully soaked in the aqueous electroplating solution in the aforesaid step B) so that materials of the alumina layer 3 and the medium deposit 4 extend through the through holes and cover top and bottom surfaces of the aluminum substrate 2. Therefore, in the aforesaid step C), the conductive wiring unit 6 extends through the through holes and is formed on the medium deposit 4 on the top and bottom surfaces of the aluminum substrate 2.

Similar to the aforesaid, when the concentration of the metal salt in the electroplating solution is relatively low or the anodization is conducted for a relatively short period, the medium deposit 4 is formed on the alumina layer 3 in a manner of medium spots disposed dispersedly on the alumina layer 3, as best shown in FIG. 7. Therefore, the third preferred embodiment shown in FIG. 6 is obtained after the conductive wiring unit 6 is formed on the medium deposit 4.

On the other hand, when the concentration of the metal salt in the electroplating solution is sufficiently high or the anodization is conducted for a sufficiently long period, the medium deposit 4 is formed on the alumina layer 3 in a manner of a layer, as best shown in FIG. 9. Therefore, the fourth preferred embodiment shown in FIG. 8 is obtained after the conductive wiring unit 6 is formed on the medium deposit 4.

Additionally, the conductive wiring unit 6 of the aluminum circuit board of the preferred embodiments can be formed with a predetermined pattern by, for example, etching.

The following examples are provided to illustrate the preferred embodiments of the invention, and should not be construed as limiting the scope of the invention.

### Examples 1-2 and Comparative Examples 1-2

Examples 1-2 and Comparative Examples 1-2 were prepared using the operating conditions listed in Table 1. The solvent for preparing the electroplating solution was water. The results of Examples 1-2 and Comparative Examples 1-2 are also listed in Table 1.

TABLE 1

| | | | Ex. 1 | Ex. 2 | Comp. Ex. 1 | Comp. Ex. 2 |
|---|---|---|---|---|---|---|
| Components for | Acid | Sulfuric | 20 wt % | 2 wt % | 20 wt % | 2 wt % |
| an | | acid | | | | |
| electroplating | | Oxalic | 10 wt % | 20 wt % | 10 wt % | 20 wt % |
| solution | | acid | | | | |
| | Total | | 30 wt % | 22 wt % | 30 wt % | 22 wt % |
| | Metal salt | Copper | 0.3 wt % | 0.4 wt % | 0 wt % | 0 wt % |
| | | sulfate | | | | |
| | | Copper | 0 wt % | 0 wt % | 0 wt % | 0 wt % |
| | | acetate | | | | |
| | | Ferric | 0.25 wt % | 0.35 wt % | 0 wt % | 0 wt % |
| | | sulfate | | | | |
| | Total | | 0.55 wt % | 0.75 wt % | 0 wt % | 0 wt % |
| | sulfactant | Sodium | 0.01 wt % | 0.01 wt % | 0.01 wt % | 0.01 wt % |
| | | sulfonate | | | | |

| | | | | | |
|---|---|---|---|---|---|
| | total | 0.01 wt % | 0.01 wt % | 0.01 wt % | 0.01 wt % |
| Aluminum | holes | No | Yes | No | Yes |
| substrate | | | | | |
| Anodization | Temperature | 10° C. | 20° C. | 10° C. | 20° C. |
| | Voltage | 50 v | 60 v | 50 v | 60 v |
| | Conducting period | 240 m | 300 m | 240 m | 300 m |
| Aluminum | Thickness of alumina | 60 μm | 60 μm | 60 μm | 60 μm |
| circuit board | layer | | | | |
| | Medium deposit | Yes | Yes | No | No |
| | Conductive wiring | Copper | Copper | Copper | Copper |
| | unit | | | | |
| | Breakdown voltage | 4000 V | 4000 V | Not | Not |
| | | | | determined | determined |
| | Coefficient of heat | 131 W/m · K | 131 W/m · K | Not | Not |
| | dissipation | | | determined | determined |

Comparative Examples 1-2 were conducted using the operating conditions respectively identical to those used for Examples 1-2 except that the electroplating solutions used in Comparative Examples 1-2 did not contain metal salts.

As shown in Table 1, the aluminum circuit boards made in Comparative Examples 1-2 were not formed with the medium deposit, and the breakdown voltages and the coefficient of heat dissipation thereof cannot be determined. Contrarily, the aluminum circuit boards made in Examples 1-2 were formed with the medium deposit, and the breakdown voltages and the coefficient of heat dissipation thereof are satisfactory. Therefore, it is demonstrated that, in the aluminum circuit board of the present invention, the conductive wiring unit can be firmly bonded to the alumina layer via the medium deposit and that the heat dissipation of the aluminum circuit board of the present invention is satisfactory.

In view of the aforesaid, the medium deposit made of nickel, copper, cobalt, iron, silver, zinc, tin, molybdenum, or combinations thereof is formed for enhancing the bonding between the conductive wiring unit and the alumina layer in the aluminum circuit board of the present invention. Therefore, the aforesaid shortcomings of the prior art due to the resin material or the colloidal silver or copper can be avoided. Furthermore, since the alumina layer and the medium deposit are formed in the same treatment, i.e., the anodization treatment, the method for making the aluminum circuit board of the present invention is simple and fast, and the production cost thereof can be reduced.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

We claim:

1. An aluminum circuit board, comprising:
a body unit including an aluminum substrate, an alumina layer formed on said aluminum substrate, and a medium deposit formed on said alumina layer and made of a material selected from the group consisting of nickel, copper, cobalt, iron, silver, zinc, tin, and molybdenum; and
a conductive wiring unit formed on said body unit and bonded to said medium deposit.

2. The aluminum circuit board as claimed in claim 1, wherein said medium deposit is disposed dispersedly on said alumina layer.

3. The aluminum circuit board as claimed in claim 1, wherein said medium deposit is a layer formed on said alumina layer.

4. The aluminum circuit board as claimed in claim 1, wherein said conductive wiring unit is made of a material selected from the group consisting of aluminum, gold, nickel, copper, cobalt, iron, silver, zinc, tin, and molybdenum.

5. The aluminum circuit board as claimed in claim 1, wherein said body unit has a top surface, a bottom surface, and a plurality of through holes extending through said top surface and said bottom surface, said conductive wiring unit extending through said through holes and being formed on said top and bottom surfaces of said body unit.

6. The aluminum circuit board as claimed in claim 1, wherein said alumina layer has a thickness ranging from 10 μm to 300 μm.

7. The aluminum circuit board as claimed in claim 1, wherein said conductive wiring unit has a pre-determined circuit pattern.

8. A method for making an aluminum circuit board, comprising the steps of:
a) preparing an electroplating solution containing 10-50 wt % of an acid, 0.01-0.05 wt % of a surfactant, 0.5-1 wt % of a metal salt, and a balance of a solvent, based on the total weight of the electroplating solution, wherein the acid is selected from the group consisting of sulfuric acid, oxalic acid, tartaric acid, sulfosalicylic acid, maleic acid, lactic acid, and, phosphoric acid, the surfactant is selected from the group consisting of sorbitol, sodium sulfonate, nitric acid, citric acid, and potassium sodium tartrate, and the metal salt is a salt of a metal selected from the group consisting of nickel, copper, cobalt, iron, silver, tin, and molybdenum;
b) soaking at least a surface of an aluminum substrate in the aqueous electroplating solution to anodize the aluminum substrate and to form an alumina layer on the aluminum substrate and a medium deposit on the alumina layer; and
c) forming a conductive wiring unit on the medium deposit.

9. The method as claimed in claim 8, wherein the metal salt is a salt of a metal selected from the group consisting of copper, iron, and molybdenum.

10. The method as claimed in claim 8, wherein the aluminum substrate has a plurality of through holes and is fully soaked in the aqueous electroplating solution in step
b) so that materials of the alumina layer and the medium deposit extend through the through holes and cover top and bottom surfaces of the aluminum substrate, and wherein, in step c), the conductive wiring unit extends through the through holes and is formed on the medium deposit on the top and bottom surfaces of the aluminum substrate.

11. The method as claimed in claim 8, wherein the anodization is conducted using an operating voltage ranging from 10 to 250 V at a temperature ranging from 0 to 40° C.

12. The method as claimed in claim 8, wherein step c) is conducted by a treatment selected from the group consisting of vapor depositing and electroplating.

13. An electroplating solution for making an aluminum circuit board, comprising:
10-50 wt %, based on said electroplating solution, of an acid selected from the group consisting of sulfuric acid, oxalic acid, tartaric acid, sulfosalicylic acid, maleic acid, lactic acid, and phosphoric acid;
0.01-0.05 wt %, based on said electroplating solution, of a surfactant selected from the group consisting of sorbitol, sodium sulfonate, nitric acid, citric acid, and potassium sodium tartrate;
0.5-1 wt %, based on said electroplating solution, of a metal salt which is a salt of a metal selected from the group consisting of nickel, copper, cobalt, iron, silver, tin, and molybdenum; and
a balance of a solvent selected from the group consisting of water, ethanol, and ethylene glycol.

14. The electroplating solution as claimed in claim 13, wherein said acid is in an amount ranging from 15 to 40 wt % based on said electroplating solution.

15. The electroplating solution as claimed in claim 13, wherein said surfactant is in an amount ranging from 0.02 to 0.04 wt % based on said electroplating solution.

16. The electroplating solution as claimed in claim 13, wherein said metal salt is in an amount ranging from 0.65 to 0.9 wt % based on said electroplating solution.

17. The electroplating solution as claimed in claim 13, wherein said metal salt is a salt of a metal selected from the group consisting of copper, iron, and molybdenum.
